(19) United States
(12) Patent Application Publication
(10) Pub. No.: US 2006/0131606 A1
(43) Pub. Date: Jun. 22, 2006

(54) Lattice-mismatched semiconductor structures employing seed layers and related fabrication methods

(75) Inventor: Zhiyuan Cheng, Lincoln, MA (US)

Correspondence Address: GOODWIN PROCTER LLP;PATENT ADMINISTRATOR, EXCHANGE PLACE, BOSTON, MA, 02109-2881, US

(73) Assignee: AmberWave Systems Corporation, Salem, NH (US)

(21) Appl. No.: 11/311,822

(22) Filed: Dec. 19, 2005

Related U.S. Application Data
(60) Provisional application No. 60/681,940, filed on May 17, 2005.
(60) Provisional application No. 60/637,132, filed on Dec. 18, 2004.

(51) Int. Cl. H01L 31/109

(52) U.S. Cl. 257/190; 438/604; 438/222

(57) ABSTRACT

Fabrication of monolithic semiconductor heterostructures and semiconductor devices based thereon employs isolated seed regions for facilitating elastic lattice conformation between the lattice-mismatched materials. Relative thicknesses of the materials are selected to introduce desirable strain distribution within the heterostructure for improved functionality and performance.

### CROSS-REFERENCE TO RELATED APPLICATIONS

This application claims priority to and the benefit of U.S. Provisional Application Ser. No. 60/681,940 filed May 17, 2005, and U.S. Provisional Application Ser. No. 60/637,132 filed Dec. 18, 2004. The entire disclosures of both of these applications are incorporated herein by reference.

### FIELD OF THE INVENTION

This invention relates generally to lattice-mismatched semiconductor heterostructures and, more specifically, to integration of dissimilar semiconductor materials employing isolated seed layers.

### BACKGROUND OF THE INVENTION

The increasing operating speeds and computing power of microelectronic devices have recently given rise to the need for an increase in the complexity and functionality of the semiconductor structures from which that these devices are fabricated. Heterointegration of dissimilar semiconductor materials, for example, III-V materials, such as gallium arsenide, gallium nitride, indium aluminum arsenide, and/or germanium with silicon or silicon-germanium substrate, is an attractive path to increasing the functionality and performance of the CMOS platform. In particular, heteroepitaxial growth can be used to fabricate many modern semiconductor devices where lattice-matched substrates are not commercially available or to potentially achieve monolithic integration with silicon microelectronics. Performance and, ultimately, the utility of devices fabricated using a combination of dissimilar semiconductor materials, however, depends on the quality of the resulting structure. Specifically, a negligible level of dislocation defects is important in a wide variety of semiconductor devices and processes, because dislocation defects partition an otherwise monolithic crystal structure and introduce unwanted and abrupt changes in electrical and optical properties, which, in turn, results in poor material quality and limited performance. In addition, the threading dislocation segments can degrade physical properties of the device material and can lead to premature device failure.

As mentioned above, dislocation defects typically arise in efforts to epitaxially grow one kind of crystalline material on a substrate of a different kind of material—often referred to as “heterostructure”—due to different crystalline lattice sizes of the two materials. This lattice mismatch between the starting substrate and subsequent layer(s) creates stress during material deposition that generates dislocation defects in the semiconductor structure.

Misfit dislocations form at the mismatched interface to relieve the misfit strain. Many misfit dislocations have vertical components, termed “threading segments,” which terminate at the surface. These threading segments continue through all semiconductor layers subsequently added to the heterostructure. In addition, dislocation defects can arise in the epitaxial growth of the same material as the underlying substrate where the substrate itself contains dislocations. Some of the dislocations thus replicate as threading dislocations in the epitaxially grown material. Such dislocations in the active regions of semiconductor devices such as diodes, lasers and transistors, may significantly degrade performance.

To minimize formation of dislocations and associated performance issues, many semiconductor heterostructure devices known in the art have been limited to semiconductor layers that have very closely—e.g. within 0.1%—lattice-matched crystal structures. In such devices a thin layer is epitaxially grown on a mildly lattice-mismatched substrate. As long as the thickness of the epitaxial layer is kept below a critical thickness for defect formation, the substrate acts as a template for growth of the epitaxial layer, which elastically conforms to the substrate template. While lattice matching and near matching eliminate dislocations in a number of structures, there are relatively few lattice-matched systems with large energy band offsets, limiting the design options for new devices.

Accordingly, there is considerable interest in heterostructure devices involving greater lattice mismatch than known approaches would allow. For example, it has long been recognized that gallium arsenide grown on silicon substrates would permit a variety of new optoelectronic devices marrying the electronic processing technology of silicon VLSI circuits with the optical component technology available in gallium arsenide. See, for example, Choi et al, “Monolithic Integration of Si MOSFETs and GaAs MESFETs”, IEEE Electron Device Letters, Vol. EDL-7, No. 4, April 1986. Highly advantageous results of such a combination include high-speed gallium arsenide circuits combined with complex silicon VLSI circuits, and gallium arsenide optoelectronic interface units to replace wire interconnects between silicon VLSI circuits. Progress has been made in integrating gallium arsenide and silicon devices. See, for example, Choi et al, “Monolithic Integration of GaAs/AlGaAs Double-Heterostructure LED's and Si MOSFETs” IEEE Electron Device Letters, Vol. EDL-7, No. 9, September 1986; Shichijo et at, “Co-Integration of GaAs MESFET and Si CMOS Circuits”, IEEE Electron Device Letters, Vol. 9, No. 9, September 1988. However, despite the widely recognized potential advantages of such combined structures and substantial efforts to develop them, their practical utility has been limited by high defect densities in gallium arsenide layers grown on silicon substrates. See, for example, Choi et at, “Monolithic Integration of GaAs/AlGaAs LED and Si Driver Circuit”, IEEE Electron Device Letters, Vol. 9, No. 10, October 1988 (p. 513). Thus, while basic techniques are known for integrating gallium arsenide and silicon devices, there exists a need for producing gallium arsenide layers having a low density of dislocation defects.

Some of the known techniques for controlling threading dislocation densities in highly-mismatched deposited layers include wafer bonding of dissimilar materials and substrate patterning. Bonding of two different semiconductors may yield satisfactory material quality. Due to the limited availability and high cost of large size Ge or III-V wafers, however, the approach may not be practical.

Techniques involving substrate patterning exploit the fact that the threading dislocations are constrained by geometry, i.e. that a dislocation cannot end in a crystal. If the free edge is brought closer to another free edge by patterning the substrate into smaller growth areas, then it is possible to reduce threading dislocation densities. In the past, a combination of substrate patterning and epitaxial lateral overgrowth (“ELO”) techniques was demonstrated to greatly reduce defect densities in gallium nitride device, leading to fabrication of laser diodes with extended lifetimes. This process substantially eliminates defects in ELO regions but highly defective seed windows remain, necessitating repetition of the lithography and epitaxial steps to eliminate all substrate defects.

Another known technique termed “epitaxial necking” was demonstrated in connection with fabricating a Ge-on-Si heterostructure by Langdo et al. in “High Quality Ge on Si by Epitaxial Necking,” Applied Physics Letters, Vol. 76, No. 25, April 2000. This approach offers process simplicity by utilizing a combination of selective epitaxial growth and defect crystallography to force defects to the sidewall of the opening in the patterning mask, without relying on increased lateral growth rates. One important limitation of epitaxial necking, however, is the size of the area to which it applies. In general, in order for the dislocations to terminate at the sidewalls, the lateral dimensions of the opening have to be relatively small compared to the thickness of the dielectric mask.

Yet another approach employs epitaxial growth of a lattice-mismatched material over one or more “seed islands,” i.e. limited regions of the seed material formed in or disposed atop the substrate. Because the seed regions are either part of or connected to the surface of the substrate, the bulky substrate limits the ability of these seed regions to adjust their lattice in order to accommodate the epitaxial growth of the lattice-mismatched material thereover. Thus, these structures are prone to formation of dislocation defects. Typically, in this approach, epitaxial growth of the lattice-mismatched material over the seed islands is followed by annealing the resulting structure to reduce the dislocation density.

Thus, there is a need in the art for versatile and efficient methods of fabricating semiconductor heterostructures that would minimize formation of dislocation defects in a variety of lattice-mismatched materials systems. There is also a need in the art for semiconductor devices utilizing a combination of integrated lattice-mismatched materials with reduced levels of dislocation defects.

### SUMMARY OF THE INVENTION

Accordingly, it is an object of the present invention to provide semiconductor heterostructures with significantly minimized defects, and methods for fabrication of such heterostructures, that address the limitations of known techniques. In its various embodiments, the present invention employs substrate-isolated seed regions for facilitating elastic lattice conformation between the lattice-mismatched materials. Also, relative thicknesses of the materials can be selected to introduce desirable strain distribution within the heterostructure for improved functionality and performance. Further, in certain aspects of the invention, direction and/or type of the strain induced within the heterostructure is controlled. As a result, the invention contemplates fabrication of a variety of semiconductor devices based on monolithic lattice-mismatched heterostructures long sought in the art but heretofore impractical due to dislocation defects.

In particular applications, the invention features semiconductor structures including Ge or III-V materials integrated with a Si substrate, as well as features methods of producing semiconductor structures that contemplate integrating Ge or III-V materials on selected seed regions over a Si substrate.

In general, in one aspect, the invention is directed to a semiconductor heterostructure that includes a substrate containing, or consisting essentially of, a first semiconductor material. A seed region containing, or consisting essentially of, a second semiconductor material, is disposed above the substrate forming a gap therebetween. The heterostructure further includes a support structure for supporting the seed region and an epitaxial region disposed adjacent to the seed region. The epitaxial region contains, or consists essentially of, a third semiconductor material. At least one of the epitaxial and the seed regions is at least partially strained.

In some embodiments of this aspect of the invention, the epitaxial region is grown on the top surface of the seed region. In other embodiments, the epitaxial region is grown on the bottom surface of the seed region. The epitaxial region can also be grown on the at least one side surface of the seed region.

In various embodiments, a ratio between the thickness of the seed region and the thickness of the epitaxial region can being selected based on a predetermined strain distribution between these regions. In some embodiments, the seed region is less than about 100 nm thick, for example, is about 50 nm thick. One of the epitaxial and the seed regions can be at least partially strained and the other can be substantially relaxed. Also, both the epitaxial region and the seed region can be at least partially strained.

The support structure can extend from the surface of the substrate and include, or consist essentially of, a dielectric material. In some embodiments, the support structure is in contact with at least one side surface of the seed region and/or in contact with at least a portion of the top surface of the seed region. In other embodiments, the support structure is in contact with at least a portion of the bottom surface of the seed region.

In this and other aspects of the invention, at least one of the first and the second semiconductor materials may contain, or consist essentially of, silicon, germanium, or a silicon germanium (“SiGe”) alloy. Also, the third semiconductor material can be selected from the group consisting of a group II, a group III, a group IV, a group V, and a group VI element, and combinations thereof, such as, for example, germanium, SiGe alloy, gallium arsenide, and gallium nitride.

Generally, in another aspect, the invention focuses on a method of fabricating a semiconductor device that begins with the step of providing a substrate having (i) a dielectric layer disposed over a base semiconductor layer, and (ii) a top semiconductor layer disposed over the dielectric layer, the base layer and the top layer containing, or consisting essentially of, silicon. The method further includes forming a seed region supported above the base layer of the substrate and defining a gap therebetween. Also, the method includes growing an epitaxial region adjacent to the seed region, wherein at least one of the epitaxial region and the seed region is at least partially strained.

Embodiments of this aspect of the invention include the following features. The step of forming a seed region may include (i) defining the seed region in the top semiconductor layer, and (ii) removing a portion of the dielectric layer thereunder. In some embodiments, the epitaxial region is grown on the top surface of the seed region and the gap between the seed region and the substrate is at least partially filed with a dielectric material. In other embodiments, the epitaxial region is grown on the bottom surface of the seed region at least partially filling the gap between the seed region and the base layer. In some version of these embodiments, the method further includes the step of (i) at least partially removing the seed region; (ii) providing a gate dielectric region over at least a portion of the epitaxial region; and (iii) providing a gate contact over the gate dielectric region.

In yet another aspect, the invention features a method of fabricating a semiconductor device that begins with providing a substrate containing, or consisting essentially of, a first semiconductor material and then providing a seed region above the substrate defining a gap therebetween. The seed region contains or consists essentially of a second semiconductor material. The method further includes growing, adjacent to the seed region, an epitaxial region comprising a third semiconductor material, wherein at least one of the epitaxial region and the seed region is at least partially strained.

In various embodiments of this aspect of the invention, the step of providing a seed region includes: (i) providing at least one sacrificial semiconductor layer over the substrate; (ii) providing a seed material layer over the sacrificial layer; (iii) defining the seed region in the seed material layer; (iv) providing a structure for supporting the seed region above the substrate, and (v) at least partially removing the sacrificial layer. The seed material layer can be at least partially strained. In many versions of these and other embodiments, as well as in other aspects of the invention, the sacrificial semiconductor layer contains, or consists essentially of, SiGe alloy.

A device area can be defined over the seed region prior to removal of the sacrificial layer, for example, by providing a gate dielectric region over at least a portion of the seed region; and providing a gate contact over the gate dielectric region.

In many embodiments, the epitaxial region is grown on the bottom surface of the seed region at least partially filing the gap between the seed region and the substrate. In this and other aspects of the invention, the substrate may include a dielectric layer disposed over a base semiconductor layer.

In general, in still another aspect, the invention features a method of fabricating a semiconductor device that includes providing a substrate containing, or consisting essentially of, a first semiconductor material and then providing an active area region supported above the substrate and defining a gap therebetween. The active area region contains, or consists essentially of, a second semiconductor material under a first type of strain. The method further includes at least partially fitting the gap with a stressed dielectric material to induce a second type of strain in the active area region. In many embodiments, one of the first and second types of strain is a tensile strain and the other is a compressive strain.

In various embodiments, the step of providing the active area region includes: (i) providing a sacrificial semiconductor layer over the substrate; (ii) providing an active area material layer under a first type of strain over the sacrificial layer; (iii) defining the strained seed region in the active area material layer; (iv) providing a structure for supporting the seed region above the substrate; and (v) at least partially removing the sacrificial layer. Prior to removal of the sacrificial layer, a gate dielectric region can be provided over at least a portion of the active area region; and then a gate contact can be provided over the gate dielectric region.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1A depict a schematic cross-sectional side view of a substrate having an isolated seed region disposed thereover;

FIG. 1B-1D depict schematic cross-sectional side views of an epitaxial region disposed adjacent to the seed region of FIG. 1A, according to various embodiments of the invention;

FIGS. 2A-2B and 2E depict schematic cross-sectional side views of the support structure supporting the seed region of FIGS. 1A-1C above the substrate;

FIGS. 2C-2D depict top views of the support structure shown in FIG. 2B, according to two alternative embodiments of the invention;

FIGS. 3A-3C illustrate various stages of fabrication of a semiconductor heterostructure, according to many embodiments of the invention;

FIGS. 3D-3E depicts schematic cross-sectional top views of two alternative configurations of the support structure supporting the seed region of FIGS. 3B-3C above the substrate;

FIG. 3F illustrate an exemplary semiconductor device based on the heterostructure of FIG. 3C;

FIGS. 4A-4C, 5A-5C, 6A-6D, 7A-7D, 8A-8C, and 9A-9D illustrate several stages of fabrication of semiconductor devices, according to various embodiments of the invention; and

FIGS. 10A-10D and 11 illustrate methods of inducing a strain within a heterostructure, according to some embodiments of the invention.

### DETAILED DESCRIPTION

The present invention generally focuses on fabrication of lattice-mismatched semiconductor heterostructures with significantly minimized dislocation defects, as well as on fabrication of various semiconductor devices based on such heterostructures. Also, in certain aspects of the invention, direction, degree, and/or type of the strain induced within the heterostructure is controlled for improved manufacturability, functionality, and performance of the semiconductor devices based thereon. In contrast with the prior art approaches of minimizing dislocation defects, in its various embodiments, the present invention addresses the limitations of known techniques, by utilizing substrate-isolated regions for facilitating elastic lattice conformation between the lattice-mismatched materials.

As mentioned above, many embodiments of the claimed invention employ semiconductor heterostructures, i.e., structures including two or more layers of semiconductor materials with different crystal lattices (e.g., silicon, germanium, and SiGe alloys). Because of the lattice mismatch, at least one of the layers has at least partially “strained” crystal lattice that enhances carrier mobility therein.

Silicon (Si) is recognized as presently being the most ubiquitous semiconductor for the electronics industry. Most of silicon that is used to form silicon wafers is formed from single crystal silicon. The silicon wafers serve as the substrate on which CMOS devices are formed. The silicon wafers are also referred to as a semiconductor substrate or a semiconductor wafer. While generally described in connection with silicon substrates, however, the use of substrates that include, or consist essentially of, other semiconductor materials, is contemplated without departing from the spirit and scope of the present invention.

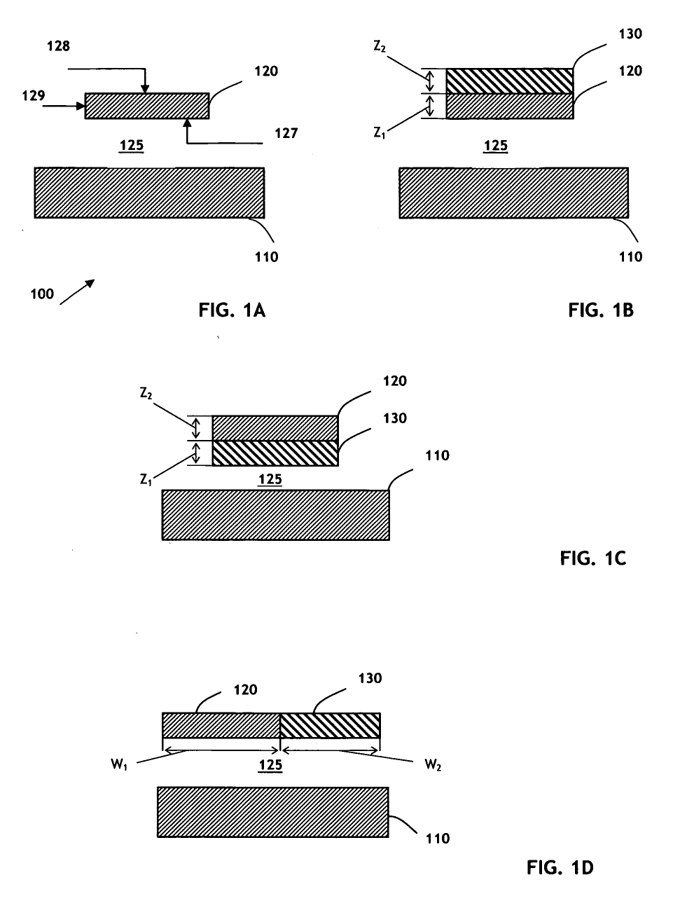

Referring to FIG. 1A, a semiconductor heterostructure 100, produced in accordance with many embodiments of the invention, includes a substrate 110. The substrate 100, suitable for use with the invention, includes, or consists essentially of, a crystalline semiconductor material, such as, for example, a bulk silicon wafer, a bulk germanium wafer, a bulk III-V wafer such as gallium arsenide or indium phosphide, a semiconductor-on-insulator (SOI) substrate, or a strained semiconductor-on-insulator (SSOI) substrate. The heterostructure further includes a seed region 120 disposed above the substrate. In various embodiments of the claimed invention, the seed region is isolated from the substrate defining a gap 125 therebetween, i.e. supported or suspended above the substrate in a manner discussed in more detail below, such that at least a portion of the bottom surface 127 of the seed region is exposed. The seed region may include, or consist essentially of, the same crystalline semiconductor material as the material of the substrate, such as, for example, silicon, or a different semiconductor material.

Referring to FIGS. 1B-1D, the semiconductor heterostructure 100 further includes an epitaxial region 130 grown over one of the surfaces of the seed region 120, i.e. over the top surface 128 (FIG. 1B), the bottom surface 127 (FIG. 1C), or one of the side surfaces 129 (FIG. 1D), the latter being particularly advantageous for fabricating FinFET-type of semiconductor devices. As skilled artisans will readily recognize, during epitaxial growth, the epitaxial region 130 retains the crystallographic orientation of the underlying material of the seed region. In the embodiments of FIGS. 1B-1D, following the epitaxial growth, the seed region may either be utilized in the semiconductor device based on the heterostructure 100, for example, having source/drain regions formed therein, or removed. In various embodiments of the invention described herein, the epitaxial region includes, or consists essentially of, a group II, a group III, a group IV, a group V, and/or a group VI element, and/or combinations thereof, for example, selected from the group consisting of germanium, SiGe alloy, gallium arsenide, and gallium nitride.

The epitaxial region can be grown in any suitable epitaxial deposition system, including, but not limited to, atmospheric-pressure CVD (APCVD), low- (or reduced-) pressure CVD (LPCVD), ultra-high-vacuum CVD (UHVCVD), or by molecular beam epitaxy. The epitaxial growth system may be a single-wafer or multiple-wafer batch reactor. The growth system also may utilize low-energy plasma to enhance the layer growth kinetics. Suitable CVD systems commonly used for volume epitaxy in manufacturing applications include, for example, EPI CENTURA single-wafer multi-chamber systems available from Applied Materials of Santa Clara, Calif., or EPSILON single-wafer epitaxial reactors available from ASM International based in Bilthoven, The Netherlands.

In the CVD process, obtaining epitaxial growth typically involves introducing a source gas into the chamber. The source gas may include at least one precursor gas and a carrier gas, such as, for example hydrogen. For example, in those embodiments of the invention where the epitaxial region is formed Ge, germanium precursor gases, such as, for example, germane, digermane, germanium tetrachloride, or dichlorogermane, or other Ge-containing precursors may be used. Also, in the embodiments where any of the regions in the heterostructure is formed from SiGe alloy, a combination of silicon and germanium precursor gases in various proportions is used.

In various embodiments, at least one of the physical dimensions of the seed region 120 and/or the epitaxial region 130 is sufficiently small to facilitate elastic lattice conformation between the lattice-mismatched materials of these regions. More specifically, still referring to FIGS. 1B-1D, in some embodiments, when thicknesses Z1 and/or Z2 (or widths W1 and/or W2 in FIG. 1D) of the substrate-isolated regions 120,130 are very small crystalline lattices of these regions are able to contract or expand to accommodate the size mismatch, thereby minimizing generation of dislocation defects in the strained material(s). In many embodiments of the invention, at least one of the thicknesses Z1 and Z2, or at least one of widths W1 and W2, is less than about 100 nm. In certain versions of these embodiments, at least one of the thicknesses Z1 and Z2, or at least one of widths W1 and W2, is less than about 50 nm, for example, is about 10 nm. In other embodiments, two dimensions of each of the regions—for example, thickness and width—are small, e.g. less than about 100 nm. In these embodiments, the other dimension of these regions, for example, the length, can be relatively large, compared to their thickness and width, enabling fabrication of large-scale semiconductor devices including a unidirectionally-strained channel region.

Still referring to FIGS. 1B-1D, in many embodiments of the invention, the ratio between thicknesses Z1, Z2 (and/or widths W1,W2) is selected to achieve a desirable strain distribution between the epitaxial region and the seed region. For example, in some versions of these embodiments, Z1 greatly exceeds Z2 and the epitaxial region is mostly strained, while the seed region is substantially relaxed. In other versions, Z2 greatly exceeds Z1 and the seed region absorbs most of the strain by changing its width and length, while the epitaxial region is substantially relaxed. In a particular version, as discussed in more detail below, a highly-stressed dielectric is grown on the bottom surface 127 in order to introduce a strain into the seed region, forming a local strained-SOI structure. Further, in some versions, Z1 substantially equal to Z2, resulting in both seed and epitaxial regions exhibiting certain degree of strain.

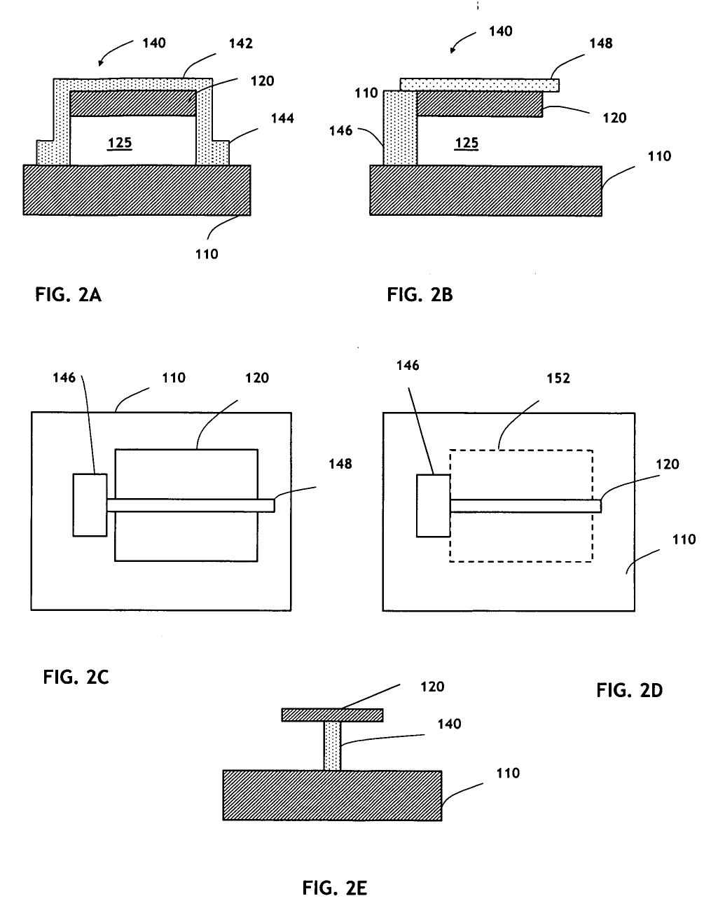

As mentioned above, being spaced apart from the bulky substrate, the seed region is capable of straining in one or more directions to accommodate the lattice mismatch with the material of the epitaxial region. Referring to FIGS. 2A-2E, in some embodiments, the seed region 120 is supported above the substrate 110 by a supporting structure 140, including, or consisting essentially of, a dielectric material, such as, for example, silicon oxide or silicon nitride. The supporting structure is preferably configured to keep the seed region above the substrate while facilitating access to the top and/or bottom surface of the seed region in the gap 125 to enable subsequent growth of the epitaxial region 130 thereover or thereunder. For example, in one embodiment, the supporting structure includes a top section 142 attached to the top surface of the seed region and at least two side sections 144 extending from the substrate 100 to the top section, as shown in FIG. 2A, forming a bridge-like structure. In some versions of this embodiment, at least one side section is also attached to the side surface of the seed region.

As CMOS devices become smaller and smaller, it becomes practical to undercut almost the entire seed region with only a point support from one side. An overlayer structure, such as a gate stack, may be used to implement such support. Referring now to FIGS. 2B-2D, in another embodiment, the supporting structure includes a side section 146 extending from the surface of the substrate and an overlayer structure 148 connected to the side section. The overlayer structure includes a gate dielectric having a gate electrode formed thereon. Referring now to FIG. 2C, in one version, the seed region 120 may cover the entire device active region, including both source/drain and channel regions. Epitaxial layer is grown under this entire region. In another version, the seed region 120 may only cover the device channel region, for example, as shown in FIG. 2D. In this version, the seed region is much narrower for process simplicity, and the source and drain material 152 may be formed separately.

In yet another embodiment, the supporting structure 140 includes a pole supporting the seed region above the substrate from the bottom, as shown in FIG. 2E. In various versions of this embodiment, a cross-section of the pole is significantly smatter than the total area of the bottom surface. In some embodiments, the pole is less than about 100 nm in lateral dimension, for example, is about 50 nm wide.

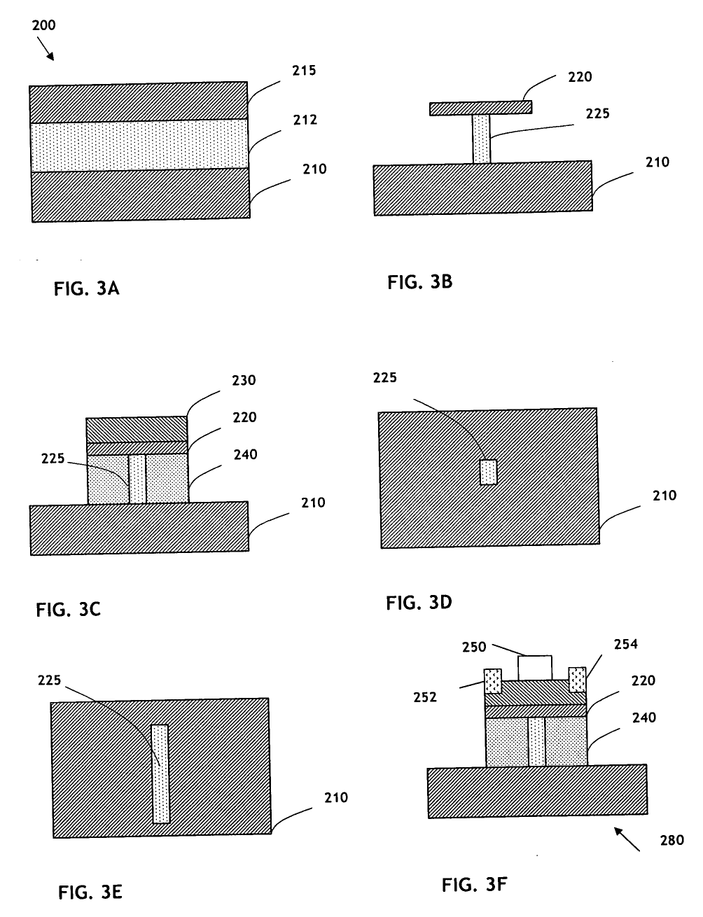

The present invention further contemplates a variety of semiconductor devices fabricated based on the heterostructures described above in connection with FIGS. 1A-1D and 2A-2E. Referring to FIG. 3A, in some embodiments, the fabrication of the semiconductor device begins with a SOI or SSOI substrate 200 including a base silicon layer 210, an insulator layer 212, and a top silicon layer 215. Referring now to FIG. 3B, a seed region 220 is dimensioned in the top layer using any of the techniques known in the art. A supporting structure 225 to support the seed region above the base layer is formed in the insulating layer by removing a portion thereof, for example, by a timed anisotropic etch. Then, an epitaxial region 230 is formed over the top surface of the seed region. Further, in many versions of these embodiments, the gap between the substrate and the seed region is fitted with a dielectric material 240, as shown in FIG. 3C. The material 240 can be the same material as the material of the insulator layer 212, or a different material.

Configurations of the supporting structure 225 defined in the insulator layer 212 can be selected depending on the desired functionality and performance of the heterostructure. For example, referring to FIG. 3D, as welt as to FIG. 2E, in some embodiments, the supporting structure is an ultra-thin pole generally centered underneath the seed region to facilitate formation of a bi-axial strain therein. In other embodiments, the supporting structure is disposed proximate to the edge of the seed region as described above in connection with FIG. 2B-2D. In yet other embodiments, the supporting structure is an elongated rib extending lengthwise underneath the seed region, facilitating formation of a unidirectional strain therein, as shown in FIG. 3E.

In some versions of the above embodiments, the epitaxial region is considerably thicker than the seed region and includes, or consists essentially of, germanium or III-V material. During the epitaxial growth of this material atop the ultra-thin quasi-free-standing structure, the silicon becomes strained, resulting in a totally or partially relaxed Ge or III-V film with greatly reduced dislocation defects. In alternative embodiments, the epitaxy and insulator removal steps are switched around, so that the epitaxial layer is deposited over the seed region before the supporting structure 225 is formed and becomes relaxed once it is formed and the seed region is able to adjust its lattice.

Referring to FIG. 3F, in various embodiments, a semiconductor device 280 is fabricated utilizing the above-described heterostructure. Further device processing steps may include the formation of a gate stack 250 by depositing a gate dielectric layer over the epitaxial region and then depositing gate electrode material(s) over the gate dielectric. One suitable technique for gate stack formation is CVD. Then, the gates are patterned by any known lithography technique and spacers are formed adjacent to the gate dielectric and gate electrode layer. The source and drain regions 252,254 are then formed by, e.g., ion implantation. The area of the epitaxial region underneath the gate stack 250 and between the source and drain regions 252,254 defines the channel region of the semiconductor devices. Also, interlayer dielectrics may be formed over gate, source, and drain, and contact holes may be defined. Metal layers may then be deposited in the contact holes and over the epitaxial region. In some embodiments, the interlayer dielectrics, for example, including, or consisting essentially of, silicon nitride, are used to induce strain within the epitaxial region.

Suitable methods for fabrication of CMOS devices, e.g. those having different n- and p-active areas, are generally described in co-pending provisional application Ser. No. 60/702,363, incorporated herein by reference. The resulting transistors may be, for example, a field-effect transistor (FET), such as a complementary metal-oxide-semiconductor FET (CMOSFET) or a metal-semiconductor FET (MESFET). In an alternative embodiment, the device is a non-FET device such as a diode. The diode device could be a light detecting device (photodiode), or a light emitting device (either a light-emitting diode, or a laser diode). In an alternative application, the device is a bipolar junction transistor.

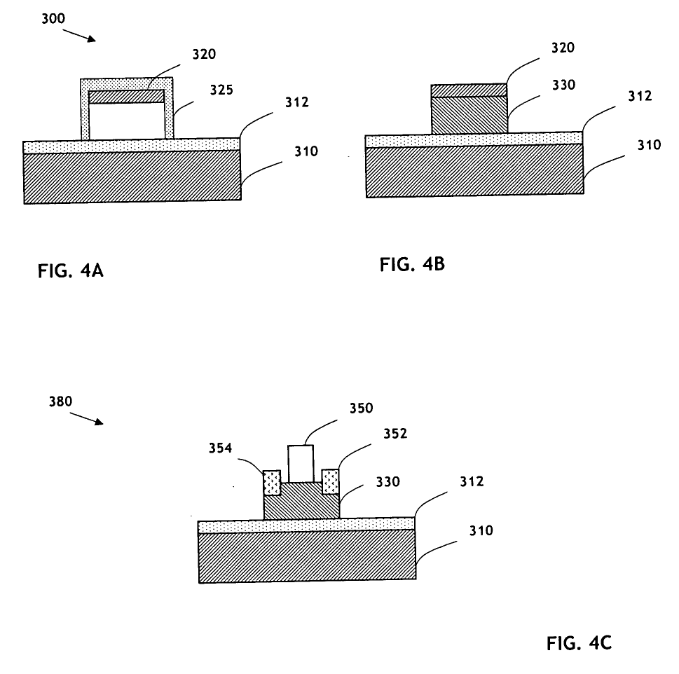

Referring to FIGS. 4A-4C, in other embodiments, fabrication of a semiconductor device also begins with a SOI or SSOI substrate including a base silicon layer 310, an insulator layer 312, and a top silicon layer (not shown). Referring now to FIG. 4A, a seed region 320 of desired dimensions is formed in the top layer using any of the techniques known in the art. Then, a portion of the insulator layer 312 is removed from underneath the seed region 320 by anisotropic etching exposing its bottom surface for epitaxial growth. In some versions, the seed region is supported above the remainder of the insulator layer 312 at the edge in a manner described above in connection with FIG. 2B. In these versions, the gate stack of the semiconductor device is preferably fabricated in the overlayer structure before the growth of epitaxial region, which simplifies the device fabrication process and minimizes interface issues. In particular, because the gate dielectric is not fabricated directly atop the epitaxial region, it is not necessary to planarize the surface of the epitaxial region after its formation or otherwise address surface roughness post-epitaxy. Also, the quality of the interface between the gate dielectric and/or high-k dielectric with the seed region is generally superior to the interface with the epitaxial region.

In other versions, still referring to FIG. 4A, a supporting structure 325 is fabricated as described above in connection with FIG. 2A. Then, an epitaxial region 330 is formed over the bottom surface of the seed region, at least partially filling the gap between the seed region and the remainder of the insulator layer 312, as shown in FIG. 4B. The remaining gap can be filled with a dielectric material, prior to device fabrication. In some versions of the above embodiments, the epitaxial region is considerably thicker than the seed region and includes, or consists essentially of, germanium or III-V material. During the epitaxial growth of this material over the bottom surface of the ultra-thin quasi-free-standing structure, the silicon becomes strained, resulting in a relaxed or partially relaxed Ge or III-V film with greatly reduced dislocation defects. Referring to FIG. 4C, in various versions of these embodiments, the supporting structure and the seed region are removed by any technique known in the art, and then one or more semiconductor devices are fabricated in the epitaxial region as described above in connection with FIG. 3F.

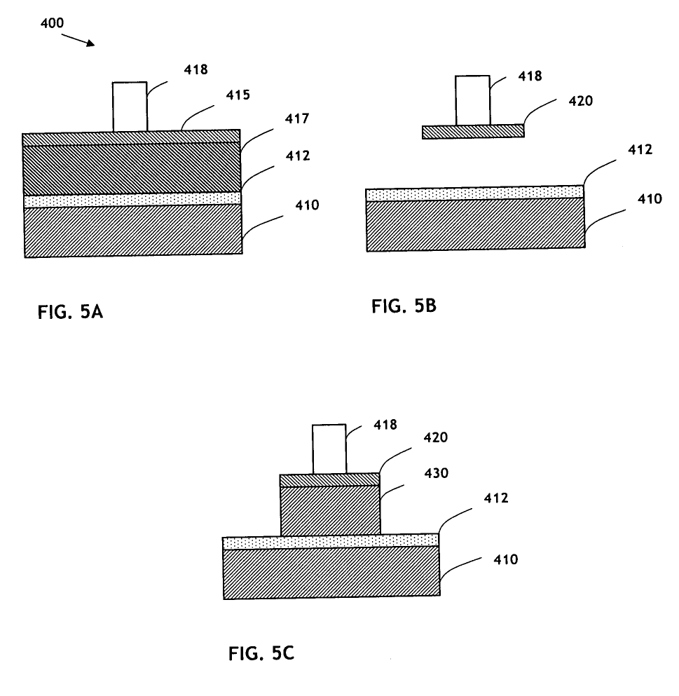

In yet other embodiments, the invention employs seed regions exhibiting certain degree of strain prior to formation of the epitaxial regions thereon. Referring now to FIGS. 5A-5C, a heterostructure 400 includes a substrate 410, for example, a bulk silicon wafer. In some embodiments, the structure also has an insulator layer 412 formed thereon. SOI or SSOI substrates can also be used. The heterostructure further includes a strained seed layer 415 and a sacrificial “virtual substrate” 417 disposed between the strained layer and the insulator layer. The seed layer may include, or consist essentially of, silicon, germanium, or SiGe alloy. In various versions of these embodiments, the sacrificial “virtual substrate” is configured to impart a desired degree of strain to the seed layer disposed thereover and includes one or more layers including, or consisting essentially of, a SiGe alloy, as described in more detail in, e.g., co-pending U.S. patent application Ser. No. 10/696,994 and U.S. Pat. No. 5,442,205, both incorporated herein by reference. In one particular version, the structure includes a SiGe alloy layer relaxed to its equilibrium lattice constant (i.e., one that is larger than that of Si) and disposed directly over the insulator layer 412. In another particular version, the relaxed SiGe is deposited atop a relaxed graded SiGe buffer layer in which the lattice constant of the SiGe material has been increased gradually over the thickness of the layer.

Still referring to FIG. 5A, the device area is patterned over the seed layer. For example, in many embodiments, a gate stack 418 is fabricated atop the seed layer by depositing a gate dielectric layer over the epitaxial region and then depositing gate electrode materials over the gate dielectric, e.g. by CVD. Then, the gates are patterned by any known lithography technique and spacers are formed adjacent to the gate dielectric and gate electrode layer. As mentioned above, fabricating the gate stack of the semiconductor device atop the seed layer before the growth of epitaxial region simplifies the device fabrication process and minimizes interface issues.

Referring to FIG. 5B, a seed region 420 is then dimensioned in the seed layer using any of the techniques known in the art and supported over the substrate 410 and the insulator layer 412 as described above in connection with FIGS. 2A-2B. In various embodiments, the sacrificial substrate 417 is at least partially removed, e.g., by etching, to expose the bottom surface of the seed region and then an epitaxial region 430 is formed over the bottom surface of the seed region extending towards the substrate 410. As mentioned above, the epitaxial region may include, or consist essentially of, a group II, a group III, a group IV, a group V, and/or a group VI element, and/or combinations thereof, for example, may be selected from the group consisting of germanium, SiGe alloy, gallium arsenide, and gallium nitride.

In some versions of these embodiments, the sacrificial structure is completely removed and the epitaxial region extends to the insulator layer 412, as shown in FIG. 5C. In other versions, a gap between the epitaxial region and the insulator layer 412 is filled with a dielectric material. Finally, one or more semiconductor devices are fabricated in the heterostructure, e.g., as described above in connection with FIG. 3F, such that the channel region of the device is at least partially defined in the epitaxial region.

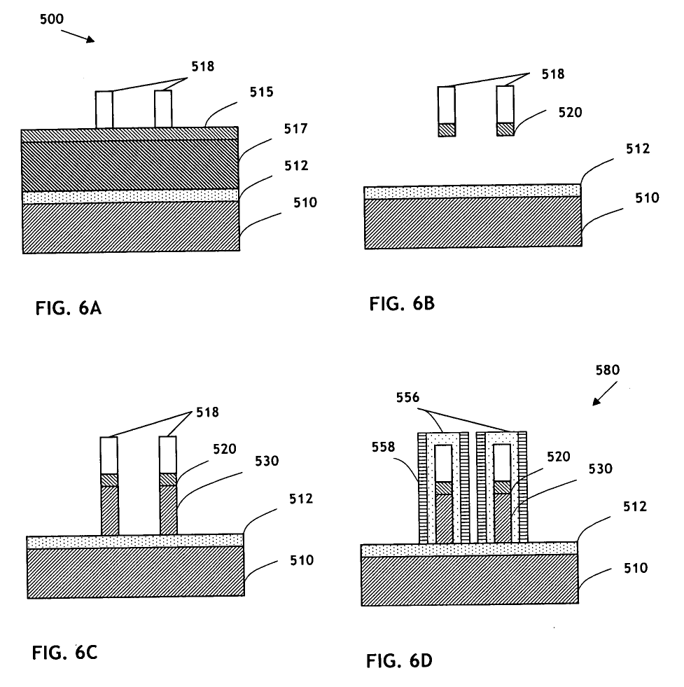

The approach described above in connection with FIGS. 5A-5C can also be employed to fabricate multi-gate FinFET devices. Referring to FIG. 6A, a heterostructure 500 includes a substrate 510, for example, a bulk silicon wafer, having an insulator layer 512 formed thereon. SOI or SSOI substrates can also be used. The heterostructure further includes a strained or non-strained seed layer 515 and a sacrificial “virtual substrate” 517 disposed between the strained layer and the insulator layer. Thickness of seed layer preferably equals to the desired thickness of the seed region. Fin areas 518 are patterned in the seed layer. Then, referring to FIGS. 6B-6C, the exposed portion of the seed layer and the sacrificial substrate are removed, resulting in formation of seed regions 520 having the fin mask regions thereover. Epitaxial regions 530 are then formed over the exposed bottom surfaces of the seed regions, as described above.

Referring to FIG. 6D, in various embodiments of the claimed invention, FinFET-type devices 580 are then formed utilizing the epitaxial regions 530 of the heterostructure 500. Further processing steps include depositing gate dielectric layers 556 over the exposed surfaces of the regions 518, 520, 530 and then forming gate electrodes 558 over the gate dielectric. In some versions of these embodiments, the seed regions and the mask 518 are removed prior to the device formation. Preferably, in these embodiments, the seed regions are extremely narrow, less than 50 nm in some embodiments, to minimize the gate length, as well as to facilitate relaxation of the epitaxial region. In a particular embodiment, the width of the seed regions 520 is about 20 nm.

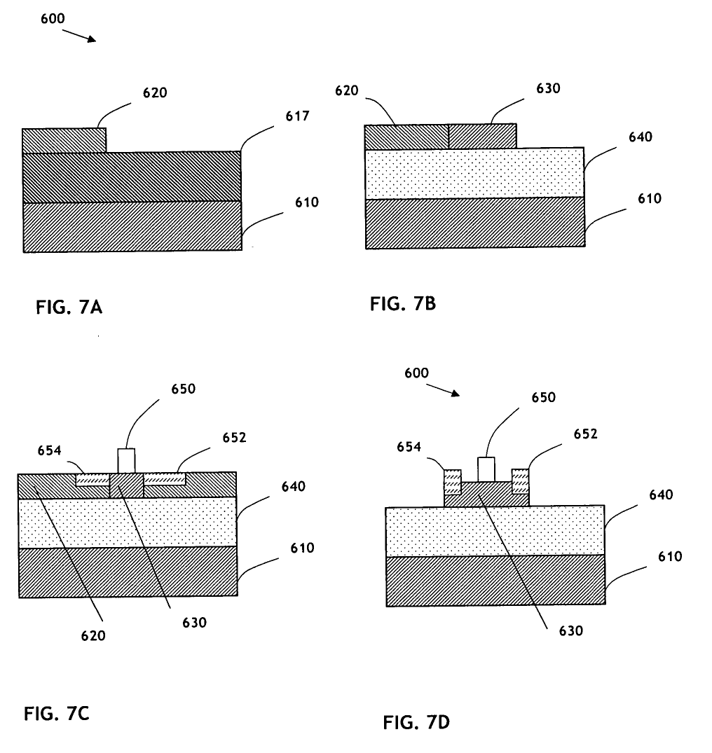

As discussed above in connection with FIG. 1C, the epitaxial region can be grown over at least one side surface of the seed region. Referring to FIGS. 7A-7D, in some embodiments, a heterostructure 600 includes a substrate 610 having an insulator layer 640 thereon and a strained or non-strained seed region 620 disposed over the insulator layer. Referring to FIG. 7A, in some versions of these embodiments, the heterostructure is formed by employing a sacrificial substrate 617, as discussed above in connection with FIG. 6A-6C, and replacing it with the insulator layer 640. In other versions, the heterostructure is fabricated from a SOI and SSOI substrate, as discussed above in connection with FIGS. 3A-3F. Referring to FIG. 7B, an epitaxial region 630 is grown over the side surface of the seed region such that the seed and the epitaxial regions are disposed side by side over the insulator layer 640, followed by chemical-mechanical polishing of the epitaxial region to reduce undesirable surface roughness. The seed region may act as a CMP stop. Then, a gate stack 650 is formed over the epitaxial region and a semiconductor device are fabricated in the heterostructure 600, e.g., as described above in connection with FIG. 3F, such that the channel region of the device is at least partially defined in the epitaxial region. The seed region can either be utilized in the device, for example, having source/drain regions 652, 654 formed therein (FIG. 7C), or removed during the device fabrication (FIG. 7D).

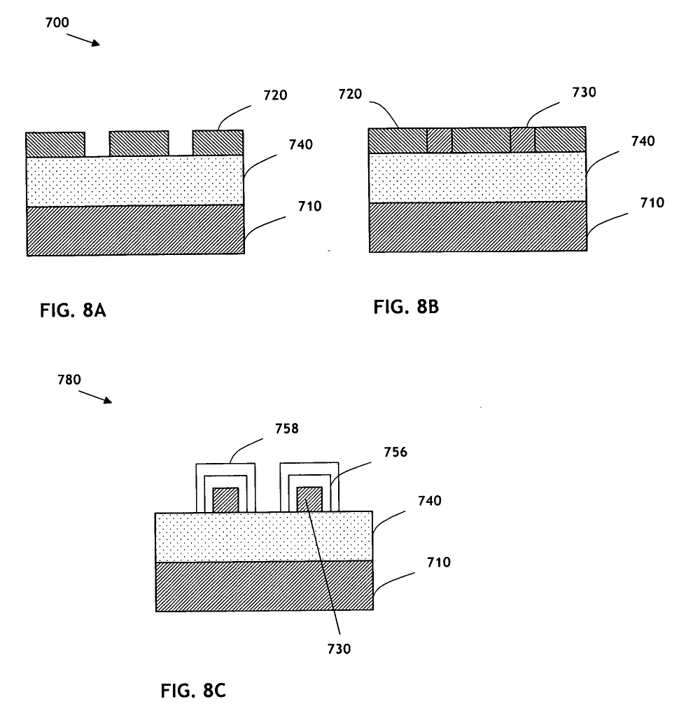

The approaches described above in connection with FIGS. 5A-5C and FIGS. 7A-7C can also be employed to fabricate multi-gate FinFET devices. Referring to FIG. 8A, in some embodiments, the fabrication of the FinFET device begins with a SOI or SSOI substrate including a base silicon layer 710, an insulator layer 740, and a top silicon layer (not shown). A plurality of seed region 720 of desired dimensions is formed in the top layer using any of the techniques known in the art. Referring to FIG. 8B, epitaxial regions 730 are grown over opposing side surfaces of the neighboring seed regions filling gapes between them, followed by chemical-mechanical polishing (CMP)of the epitaxial regions to reduce undesirable surface roughness. The seed regions may act as CMP stops. Referring now to FIG. 8C, the seed regions 720 are removed and then FinFET-type devices 780 are formed utilizing the epitaxial regions 730. Further processing steps include depositing gate dielectric layers 756 over the exposed surfaces of the epitaxial regions, and then forming gate electrodes 758 over the gate dielectric.

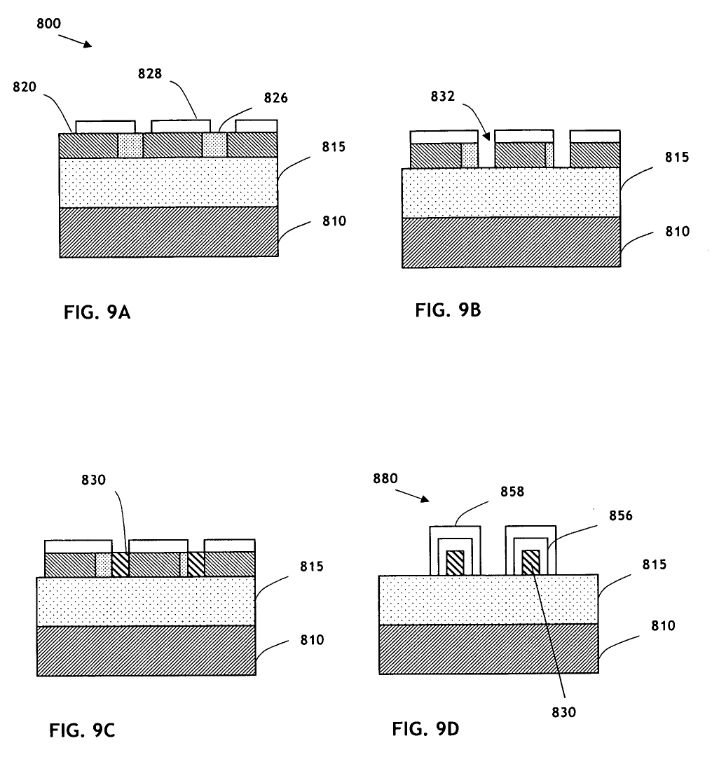

In alternative embodiments, fabrication of the multi-gate FinFET devices first proceeds as discussed in connection with FIG. 8A, such that a plurality of seed regions 820 is formed over an insulator layer 815 disposed over a base silicon layer 810, as shown in FIG. 9A. Then, in contrast to the above approach, the gaps between the seed regions are filled with a dielectric material, e.g., silicon dioxide, forming dielectric regions 826. Following an optional CMP step, a mask 828 is disposed over the regions 820, 826 alternately covering and exposing interfaces between the regions 820 and 826. Exposed portions of the regions 820 and 826 are then removed, e.g., by etching, as shown in FIG. 9B, forming substantially identical openings 832 therethrough, e.g. extending to the underlying insulator layer 740, so that all the openings has one sidewall consisting of a new side surface of the seed region 820, and the opposite sidewall consisting of a new side surface of the dielectric region 826. Referring to FIG. 9C, epitaxial regions 838 are formed on the exposed side surfaces of the seed regions filling the openings 832. Then, the mask 828 and the regions 820, 826 are removed and FinFET-type devices 880 are formed utilizing the epitaxial regions 830, e.g. in a manner described above. Further processing steps may include depositing gate dielectric layers 856 over the exposed surfaces of the epitaxial regions and then forming gate electrodes 858 over the gate dielectric layers.

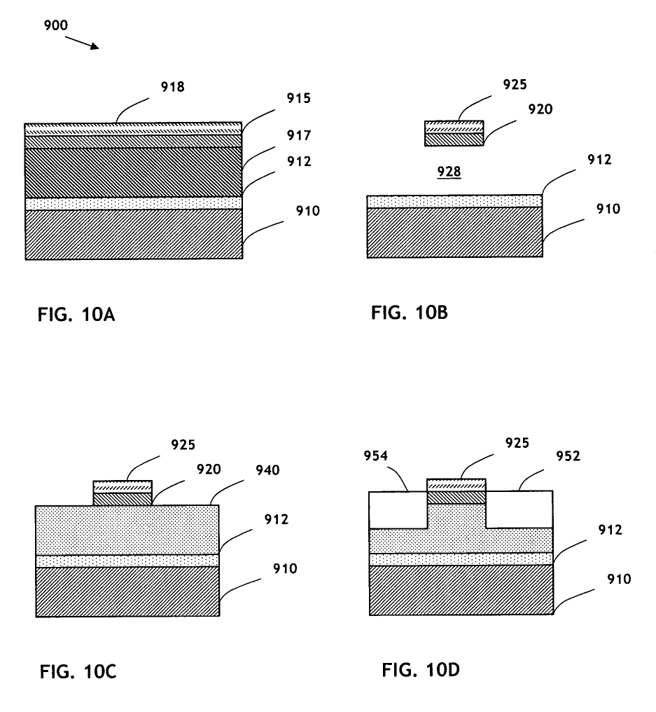

In another aspect, the invention contemplates applying some of the approaches described above, e.g., in connection with FIGS. 4A-4C and 5A-5C, to manipulate the type, degree, and direction of the strain in the topmost layer of an “on-insulator”-type semiconductor heterostructure. More particularly, in various embodiments, lattice-mismatched materials, e.g. highly-stressed dielectrics, are employed to induce a desired type, degree, and direction of strain in the adjacent semiconductor region. Referring to FIG. 10A, in some embodiments, the heterostructure 900 includes a substrate 910 having a sacrificial semiconductor structure 917 disposed thereover. An active area layer 915 is epitaxially grown over the sacrificial semiconductor structure. An etch-stop layer 912, e.g. a dielectric layer or a semiconductor layer such as SiGe layer, can be disposed between the sacrificial structure and the substrate. In many versions of these embodiments, the sacrificial structure is a “virtual substrate” configured to impart a desired degree of strain to the layer 915 disposed thereover and includes one or more layers including, or consisting essentially of, a SiGe alloy, e.g., a SiGe layer relaxed to its equilibrium lattice constant (i.e., one that is larger than that of Si) and either disposed directly over the etch-stop layer 912 (or the substrate 900) deposited atop a relaxed graded SiGe buffer layer in which the lattice constant of the SiGe material has been increased gradually over the thickness of the layer. In certain versions, the active area layer 915 consists essentially of Si and is under bi-axial tensile strain induced by the underlying SiGe structure. A dielectric layer 918 is disposed over the active area layer 915.

Referring to FIG. 10B, a patterning mask (not shown) is applied over the structure 900 and a semiconductor device is defined by removing exposed portions of the layers 918, 917, and 918, thereby forming an active area region 920. A gate stack 925 is then formed over the active area region, as described above in connection with, e.g., FIG. 3F. Then, the sacrificial structure 917 is removed while keeping the active area region spaced above the substrate 400, e.g. as described above in connection with FIGS. 2A-2B, forming a gap 928 therebetween. The gap 928 is then filled with a material 940 that is lattice-mismatched to the material of the active area region, e.g. a highly-stressed dielectric, such as silicon nitride, inducing additional strain, e.g. compressive strain, in the active area region, as shown in FIG. 10C. As skilled artisans will appreciate, the degree, direction, and type of the additional strain depend on the lattice mismatch between the material 940 and the active area region 920, and can be controlled by selecting a particular lattice-mismatched material to achieve desirable functionality and performance. Referring to FIG. 10D, semiconductor device fabrication further includes regrowing source and drain regions 952, 954 over the material area 940 adjacent to the active area region using any of the methods known in the art. A channel region of the semiconductor device is defined in the active area region between the source and drain regions. In various embodiments, the source and drain regions extend above the material area 940 forming a raised structure. In some versions of these embodiments, the source and drain region further contribute to inducing the strain in the channel region of the device.

Among other advantages, the strain-inducing approach described above can be used to fabricate a variety of semiconductor devices, including planar and non-planar FET, e.g. DG, FinFET and multi-gate devices employing a wide range of materials. Further, because of the active area layer is deposited epitaxially, rather than by wafer-bonding, the film uniformity and material quality is improved. In addition, OI (“On-insulator”) devices employing different stress-inducing and/or source and drain materials, as well as planar and non-planar devices can be fabricated on the same platform. For example, this approach allows to optimize fabrication of n- and p-FETs separately, as well as to combine different types of strain. Referring to again to FIGS. 10A-10D, an n-FET and a p-FET can be fabricated over the substrate 910 by utilizing tensilely strained material 940 and source/drain regions consisting essentially of silicon carbide to fabricate the n-FET device and compressively strained material 940 and source/drain regions consisting essentially of SiGe alloy to fabricate the p-FET device.

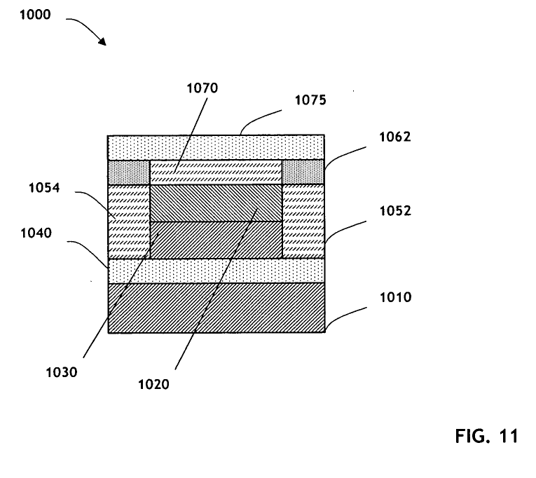

Moreover, when employed in conjunction with fabrication of nanometer-scale devices, the approach described above can be used to induce a desired type, degree, and direction of the strain in the channel material, including a three-dimensional strain, by several components of the device. Referring to FIG. 11, a nanoscale semiconductor device 1000 fabricated over an OI substrate 1010 includes a stressed dielectric layer 1040 disposed over the substrate, a channel region 1020 having an epitaxial region 1030 grown over its bottom surface extending to the stressed dielectric layer, raised source/drain regions 1052, 1054 formed over the stressed dielectric layer adjacent to the channel region, a gate stack 1070 including a high-k gate dielectric layer disposed over the channel region and a gate electrode deposited over the gate dielectric layer, a second stressed dielectric layer 1075 disposed over the gate stack, and STI regions 1062 surrounding the device. In various embodiments, one or more of the components 1040, 1030, 1052, 1054, 1070, 1075, and 1062 are engineered to induce a desired strain in the channel region. The structures and methods described in this invention, in particular the structures and methods described in FIGS. 10A-10D, can be employed in conjunction with abovementioned components, so that the device structure has optimized strain distribution for device performance enhancement. In certain versions, the channel region consists essentially of silicon, the epitaxial region consists essentially of germanium or gallium arsenide, and the stressed dielectric layers include silicon nitride.

Other embodiments incorporating the concepts disclosed herein may be used without departing from the spirit of the essential characteristics of the invention or the scope thereof. The foregoing embodiments are therefore to be considered in all respects as only illustrative rather than restrictive of the invention described herein. Therefore, it is intended that the scope of the invention be only limited by the following claims.

1. A semiconductor heterostructure comprising:
(a) a substrate having a surface and comprising a first semiconductor material;
(b) a seed region disposed above the substrate forming a gap therebetween, the seed region having a top surface, a bottom surface, and at least one side surface and comprising a second semiconductor material;
(c) a support structure for supporting the seed region; and
(d) an epitaxial region disposed adjacent to the seed region and comprising a third semiconductor material, wherein at least one of the epitaxial region and the seed region is at least partially strained.

2. The semiconductor heterostructure of claim 1 wherein the epitaxial region is grown on the top surface of the seed region.

3. The semiconductor heterostructure of claim 1 wherein the epitaxial region is grown on the bottom surface of the seed region.

4. The semiconductor heterostructure of claim 1 wherein the epitaxial region is grown on the at least one side surface of the seed region.

5. The semiconductor heterostructure of claim 1 wherein the seed region has a first thickness and the epitaxial region has a second thickness, a ratio between the first thickness and the second thickness being selected based on a predetermined strain distribution between the epitaxial region and the seed region.

6. The semiconductor heterostructure of claim 5 wherein the first thickness is less than about 100 nm.

7. The semiconductor heterostructure of claim 5 wherein one of the epitaxial region and the seed region is at least partially strained and the other is substantially relaxed.

8. The semiconductor heterostructure of claim 5 wherein the epitaxial region and the seed region are at least partially strained.

9. The semiconductor heterostructure of claim 1 wherein the support structure extends from the surface of the substrate and comprises a dielectric material.

10. The semiconductor heterostructure of claim 9 wherein the support structure is in contact with the at least one side surface of the seed region.

11. The semiconductor heterostructure of claim 9 wherein the support structure is in contact with at least a portion of the top surface of the seed region.

12. The semiconductor heterostructure of claim 9 wherein the support structure is in contact with at least a portion of the bottom surface of the seed region.

13. The semiconductor heterostructure of claim 1 wherein at least one of the first and the second semiconductor materials comprises silicon, germanium, or a SiGe alloy.

14. The semiconductor heterostructure of claim 1 wherein the third semiconductor material is selected from the group consisting of a group II, a group III, a group IV, a group V, and a group VI element, and combinations thereof.

15. The semiconductor heterostructure of claim 14 wherein the third semiconductor material is selected from the group consisting of germanium, SiGe, gallium arsenide, and gallium nitride.

16. A method of fabricating a semiconductor device, the method comprising:
(a) providing a substrate comprising:
(i) a dielectric layer disposed over a base semiconductor layer, and
(ii) a top semiconductor layer disposed over the dielectric layer, the base layer and the top layer comprising silicon;
(b) forming a seed region supported above the base layer of the substrate and defining a gap therebetween, the seed region having a top surface and a bottom surface; and
(c) growing an epitaxial region adjacent to the seed region, wherein at least one of the epitaxial region and the seed region is at least partially strained.

17. The method of claim 16 wherein step (b) comprises:
(i) defining the seed region in the top semiconductor layer, and
(ii) removing a portion of the dielectric layer thereunder.

18. The method of claim 17 wherein the epitaxial region is grown on the top surface of the seed region, the method further comprising at least partially filing the gap between the seed region and the substrate with a dielectric material.

19. The method of claim 16 wherein the epitaxial region is grown on the bottom surface of the seed region at least partially filling the gap between the seed region and the base layer.

20. The method of claim 19, further comprising:
(i) at least partially removing the seed region;
(ii) providing a gate dielectric region over at least a portion of the epitaxial region; and
(iii) providing a gate contact over the gate dielectric region.

21. The method of claim 16 wherein the epitaxial region comprises a semiconductor material selected from the group consisting of a group II, a group III, a group IV, a group V, and a group VI element, and combinations thereof.

22. The method of claim 21 wherein the semiconductor material is selected from the group consisting of germanium, SiGe, gallium arsenide, and gallium nitride.

23. A method of fabricating a semiconductor device, the method comprising:
(a) providing a substrate comprising a first semiconductor material;
(b) providing a seed region above the substrate and defining a gap therebetween, the seed region having a top surface and a bottom surface and comprising a second semiconductor material; and
(c) growing, adjacent to the seed region, an epitaxial region comprising a third semiconductor material, wherein at least one of the epitaxial region and the seed region is at least partially strained.

24. The method of claim 23 wherein the step (b) comprises:
(i) providing at least one sacrificial semiconductor layer over the substrate;
(ii) providing a seed material layer over the sacrificial layer;
(iii) defining the seed region in the seed material layer;
(iv) providing a structure for supporting the seed region above the sub; and
(v) at least partially removing the sacrificial layer.

25. The method of claim 24 wherein the seed material layer is at least partially strained.

26. The method of claim 25 wherein step (b) comprises, prior to substep (v), defining a device area over the seed region.

27. The method of claim 26 wherein the device area is defined by
providing a gate dielectric region over at least a portion of the seed region; and
providing a gate contact over the gate dielectric region.

28. The method of claim 24 wherein the sacrificial semiconductor layer comprises SiGe alloy.

29. The method of claim 23 wherein the epitaxial region is grown on the bottom surface of the seed region at least partially filing the gap between the seed region and the substrate.

30. The method of claim 23 wherein the substrate comprises a dielectric layer disposed over a base semiconductor layer.

31. The method of claim 23 wherein at least one of the first and the second semiconductor materials comprises silicon or a SiGe alloy.

32. The method of claim 23 wherein the third semiconductor material is selected from the group consisting of a group II, a group III, a group IV, a group V, and a group VI element, and combinations thereof.

33. The method of claim 32 wherein the third semiconductor material comprising at least one of germanium, SiGe, gallium arsenide, and gallium nitride.

34. A method of fabricating a semiconductor device, the method comprising:
(a) providing a substrate comprising a first semiconductor material;
(b) providing an active area region supported above the substrate and defining a gap therebetween, the active area region comprising a second semiconductor material at least partially under a first type of strain; and
(c) at least partially filling the gap with a stressed dielectric material to induce a second type of strain in the active area region.

35. The method of claim 34 wherein step (b) comprises:
(i) providing a sacrificial semiconductor layer over the substrate;
(ii) providing an active area material layer at least partially under a first type of strain over the sacrificial layer;
(iii) defining the active area region in the seed material layer;
(iv) providing a structure for supporting the active area region above the substrate; and
(v) at least partially removing the sacrificial layer.

36. The method of claim 35 wherein step (b) comprises, prior to substep (v)
providing a gate dielectric region over at least a portion of the active area region; and
providing a gate contact over the gate dielectric region.

37. The method of claim 35 wherein the sacrificial semiconductor layer comprises SiGe alloy.

38. The method of claim 34 wherein the substrate comprises a dielectric layer disposed over a base semiconductor layer.

39. The method of claim 34 wherein at least one of the first and the second semiconductor materials comprises silicon, germanium, or a SiGe alloy.

40. The method of claim 34 wherein one of the first and second types of strain is a tensile strain and the other is a compressive strain.
